(19) United States
(12) Patent Application Publication
(10) Pub. No.: US 2008/0129309 A1
(43) Pub. Date: Jun. 5, 2008

(54) Method For Detecting and Locating a Ground Failure In an Electrical Line

(75) Inventor: Giovanni Cannistra, Bologna (IT)

Correspondence Address: WILLIAM J. SAPONE;COLEMAN SUDOL SAPONE P.C., 714 COLORADO AVENUE, BRIDGE PORT, CT, 06605, US

(73) Assignee: O.C.E.M. S.P.A., S. Giorgio di Piano (IT)

(21) Appl. No.: 11/814,179

(22) PCT Filed: Jan. 18, 2006
(86) PCT No.: PCT/IB06/00070

§ 371 Date: Jul. 18, 2007

(30) Foreign Application Priority Data
Jan. 19, 2005 (IT) BO2005A 000023

(51) Int. Cl. G01R 31/08

(52) U.S. Cl. 324/527

(57) ABSTRACT

A method for detecting and locating a ground failure in an electrical line, of the type comprising a plurality of electrical loads connected to an electrical line (L) and supplied by a supply and control apparatus (1), each electrical load consisting of a load element and an auxiliary device, electrically connected to each other, with said method providing for: the transmission, over the electrical line (L), of at least a first control signal ((S(i,i+1))) from a first auxiliary device (Dᵢ), associated to a corresponding first load (Cᵢ) belonging to the plurality of electrical loads, to a second auxiliary device ((Di+1)), associated to a corresponding second load ((Ci+1)), adjacent the first load (Cᵢ), belonging to the plurality of electrical loads; the reception of the first control signal ((S(i,i+1))), transmitted by the first auxiliary device (Dᵢ), by the second auxiliary device ((Di+1)); the transmission of a first information signal (Inf(i+1,i)) to the supply and control apparatus (1) by the second auxiliary device ((Di+1)).

### TECHNICAL SCOPE

The present invention relates the to technical field of the control of the operating status of electrical systems consisting, for example, of meshes including loads arranged in series, with specific reference to public and airport lighting systems.

### DESCRIPTION OF THE PRIOR ART

In the field of lighting, different types of lamps are known, such as low or high pressure, mercury vapours, incandescence, halides, and so on, wherein the emitted light flow depends on the intensity of the electrical current circulating therein; as a consequence, outdoor or public lighting systems, for example, require the connection of the corresponding electrical loads in a series, with circulation of a same current in each of them, to allow as even as possible lighting of the environment, that is, of the road surface.

Public lighting systems, in particular, generally have a considerable size, which requires the installation, on each lamp powered by a relevant current transformer, of auxiliary devices capable of communicating the proper operating condition of the lamp itself to a control unit, placed at the same power supply apparatus; besides integrating more additional functions, such devices operate, in short circuit condition, for example a branch located in parallel to the lamp, thus preventing the onset of dangerous overvoltages at the terminals of the latter in the event of breakage. The “communication” between each auxiliary device and the control unit, for example, through the so-called line carrier system, which allow the use of the same power line as a means for the transmission of information signals; in this way the control unit, through the power supply line and according to the so-called polling technique, polls each device individually, which makes the operating status of the associated lamp known. In this way it is possible to know, with a time delay depending on the number of loads present in the system, when and which lamp is out of order, thus allowing the replacement thereof.

At present, electrical systems of a certain size and number of loads, exhibit considerable disadvantages when one or more ground failures occur, both for detecting the current to ground, sometimes not sensed by the relevant apparatus (such as circuits with branched loads) and for the exact location of the failure point or points. In circuits with loads in series, in particular, the failed triggering of the operating means for disconnecting the system could pose a serious hazard for the safety of the nearby people (direct contact with parts connected to a voltage source).

To detect a ground failure, some power supply sources are provided with additional equipment which sets a “direct” potential difference at the line conductors; in operating conditions, therefore, an alternating current circulates in the power circuit, obtained by the sum of a sinusoidal power supply current and a direct component. In the event of a ground failure, a part of the direct current closes along a circuit that includes the additional equipment, provided with an amperometer and referred to ground, the ground itself and a portion of power supply conductor up to the failure point.

However, such detection technique cannot provide any information regarding the exact ground failure point.

To make things worse, it is noted that no effective techniques or methods are known for the prompt detection of the exact failure point, so the resulting problems can sometimes be unacceptable: in the event of a failure, in fact, the engineers move from one point of the system to the other, each time insulating portions of the circuit and carrying out, for example, resistance measurements by bridge methods; as it can be easily understood, such operations require much time for detecting the failure point. As a possible consequence thereof, this could bring to the manufacture of systems with an insulation degree, for example, higher than what required by the specific regulations.

### SUMMARY OF THE INVENTION

The object of the present invention is to propose a method for detecting and locating a ground failure in an electrical line, which should allow detecting and locating in a short time any ground failure in an electrical circuit consisting of loads connected in series with one another or branched from a power supply line.

The above object is achieved, in accordance with the contents of the claims, by a method for detecting and locating a ground failure in an electrical line to which there are connected electrical loads powered by a power supply and control apparatus, each electrical load consisting of a load element and of an auxiliary device, electrically connected to each other, characterised in that it provides for:
a. transmitting, on said electrical line, at least one first control signal from a first auxiliary device, associated to a corresponding first load, to a second auxiliary device, associated to a corresponding second load;
b. receiving said first control signal, transmitted by the first auxiliary device, by the second auxiliary device;
c. transmitting a first information signal, to said power supply and control apparatus, by said second auxiliary device.

According to a variation thereof, the method provides for:
a. transmitting, on said electrical line, at least one first control signal from a first auxiliary device, associated to a corresponding first load, to a second auxiliary device, associated to a corresponding second load;
b. transmitting, on said electrical line, at least a second control signal from said second auxiliary device, associated to said corresponding second load, to said first auxiliary device, associated to said corresponding first load;
c. receiving said first control signal, transmitted by the first auxiliary device, by said second auxiliary device;
d. receiving said second control signal, transmitted by said second auxiliary device, by said first auxiliary device;
e. transmitting a first information signal, to said power supply and control apparatus, by said second auxiliary device.
f. transmitting a second information signal, to said power supply and control apparatus, by said first auxiliary device.

### BRIEF DESCRIPTION OF THE DRAWINGS

The features of the invention, not appearing from the aforesaid, will appear more clearly from the following description, in accordance with the claims and with reference to the annexed drawing tables, wherein:

FIG. 1 shows the wiring diagram of a circuit consisting of loads connected in series and powered by a power supply and control apparatus;

FIG. 2 shows the wiring diagram of the circuit of FIG. 1, wherein there occurred a ground failure in a portion comprised between two generic loads;

FIG. 3 shows the wiring diagram of a circuit consisting of loads placed in branching from an electrical line and powered by a power supply and control apparatus, according to an embodiment variation;

FIG. 4 shows the wiring diagram of the circuit of FIG. 3, wherein there occurred a failure in conductor in a portion comprised between two generic loads;

FIGS. 5, 6 show, for simplicity, the same failure of FIG. 2, but they refer to an embodiment variation of the subject method.

### DESCRIPTION OF THE PREFERRED EMBODIMENTS

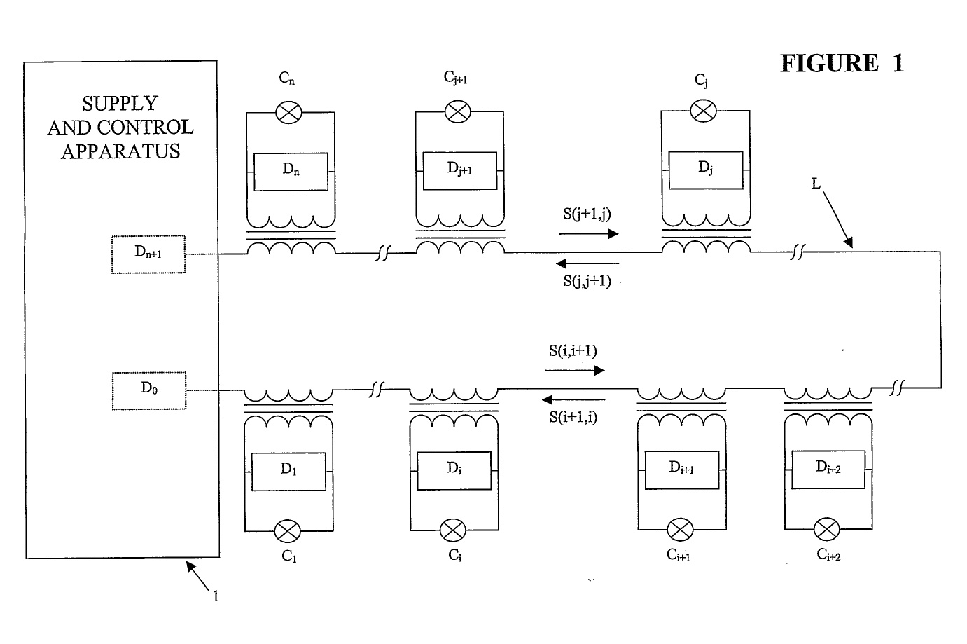

With reference to the annexed drawing tables, reference numeral 1 denotes a power supply and control apparatus, intended for powering an electrical circuit L consisting of a plurality of electrical loads C₁, . . . , Cᵢ, Cᵢ₊₁, Cᵢ₊₂, . . . , Cⱼ, Cⱼ₊₁, . . . , Cₙ which, in the example shown in FIG. 1, are connected in series with one another; with reference to such figure, each electrical load Cᵢ comprises, for example, a current transformer having the primary winding in series on the electrical circuit L and the secondary winding that powers in parallel a load element, such as a lamp, and an auxiliary device Dᵢ, comprising a power supply source and a receiver-transmitter apparatus.

The power supply and control apparatus 1, besides powering said electrical circuits, is capable of communicating on the same electrical circuit L and for example, by means of conveyed waves, with the auxiliary devices D₁, . . . , Dᵢ, Dᵢ₊₁, Dᵢ₊₂, . . . , Dⱼ, Dⱼ₊₁, . . . , Dₙ according to the modes as described in the following. The description of the method refers, for example, to any two adjacent electrical loads Cᵢ and Cᵢ₊₁, hereinafter respectively referred to as first and second electrical load Cᵢ, Cᵢ₊₁, as well as the elements forming them and the signals they generate, for higher clarity of description. The method of the present invention provides for:
transmitting, on the electrical line L and by means of conveyed waves, at least a first control signal S(i,i+1) from a first auxiliary device Dᵢ, associated to a first load Cᵢ, to a second auxiliary device Dᵢ₊₁, associated to a corresponding second electrical load Cᵢ₊₁;
transmitting, on said electrical line L and by means of conveyed waves, at least a second control signal S(i+1,i) from the second auxiliary device Dᵢ₊₁, to the first auxiliary device Dᵢ;
receiving said first control signal S(i,i+1) by the second auxiliary device Dᵢ₊₁;
receiving said second control signal S(i,i+1) by the first auxiliary device Dᵢ;
transmitting, on said electrical line L and ny means of conveyed waves, a first information signal Inf(i+1,(i)), to the power supply and control apparatus 1, by the second auxiliary device Dᵢ₊₁;
transmitting, on said electrical line L and by means of conveyed waves, a second information signal Inf(i,(i+1)), to the power supply and control apparatus 1, by the first auxiliary device Dᵢ.

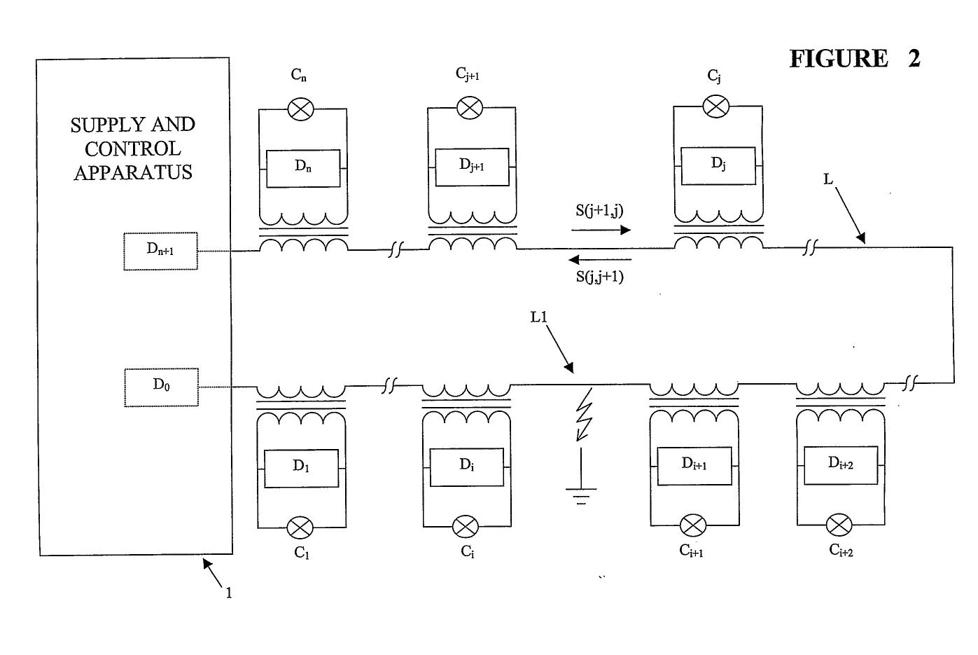

Based on the method described above, it is clear that each auxiliary device, such as the second device Dᵢ₊₁, associated to the second load Cᵢ₊₁, communicates with the auxiliary devices Dᵢ₊₂ and Dᵢ of the adjacent loads, for example with a periodical frequency. FIG. 2 shows a generic ground failure in the circuit portion L1 comprised between the first Cᵢ and the second electrical load Cᵢ₊₁, for example; in that case, the transmission, as well as the reception, of the first and second control signal S(i,i+1), S(i+1,i), by the first and second auxiliary device Dᵢ, Dᵢ₊₁, is altered, in the values and patterns, by the presence of said failure between the first and the second electrical load Cᵢ, Cᵢ₊₁. In fact, an alteration of the control signals passing close to the failure point of any electrical line has been experimentally noted; such alteration, if the same control signals have frequencies falling within certain ranges, exhibits features differing from any other anomaly or noise that could set.

In the light of the above, the subject method provides for the first and the second information signal Inf(i+1,(i)), Inf(i,(i+1)), sent to the power supply and control apparatus 1 for example with periodical frequency, to contain at least a portion respectively of the first and second control signals S(i,i+1), S(i+1,i); in this way, the power supply and control apparatus 1 can check, after analysing the above information signals, the presence of any generic ground failures between the electrical loads Cᵢ and Cᵢ₊₁. As an alternative, such analysis of the first and second control signal S(i,i+1), S(i+1,i) can be carried out during the reception of the latter respectively by the second and first auxiliary device Dᵢ₊₁, Dᵢ; in the event of a failure between said first and second electrical load Cᵢ, Cᵢ₊₁, the associated auxiliary devices Dᵢ₊₁, Dᵢ respectively send a second and a first information signals Inf(i,(i+1)), Inf(i+1,(i)) to the power supply and control apparatus 1, which is therefore informed of the presence of the failure between the electrical loads.

The signals circulating on the electrical line L, for example the control signals S(i,i+1), S(i+1,i), contain an identification code that differentiates them from the others, allowing their recognition by the auxiliary devices that receive them. Said first control signal S(i,i+1), for example is recognised, acquired and optionally processed by the auxiliary devices of the loads adjacent the first electrical load Cᵢ, thanks to such identification code, whereas it is ignored by all the others auxiliary devices.

As an alternative, the information signals, in the above example signals Inf(i,(i+1)), Inf(i+1,(i)), can be transmitted by means of electromagnetic waves by said auxiliary devices, in the example Dᵢ, Dᵢ₊₁, to the power supply and control apparatus 1.

The above method allows detecting and locating a ground failure in the electrical circuit L also in the case where only one between said first control signal S(i,i+1) and second control signal S(i+1,i) is transmitted between generic auxiliary devices, for example said first and second device Dᵢ, Dᵢ₊₁, If for example we consider the transmission of only the first signal S(i,i+1) from the first auxiliary device Dᵢ, associated to the first load Cᵢ, to the second auxiliary device Dᵢ₊₁, associated to the second load Cᵢ₊₁, adjacent the first one, the reception of such first signal S(i,i+1) will cause the consequent transmission, optional or systematic, according to the modes described above, of said first information signal Inf(i+1,(i)).

The power supply and control apparatus 1 comprises electrical loads, connected to the ends of the electrical line L and of which, for simplicity, only the associated auxiliary devices D₀ and Dₙ₊₁, have been indicated, which add up to said plurality of electrical loads C₁, . . . , Cᵢ, Cᵢ₊₁, Cᵢ₊₂, . . . , Cⱼ, Cⱼ₊₁, . . . , Cₙ, since the control and information signals are managed similarly as described above: in this way it is possible to detect and locate any generic ground failure in any point of the electrical circuit L.

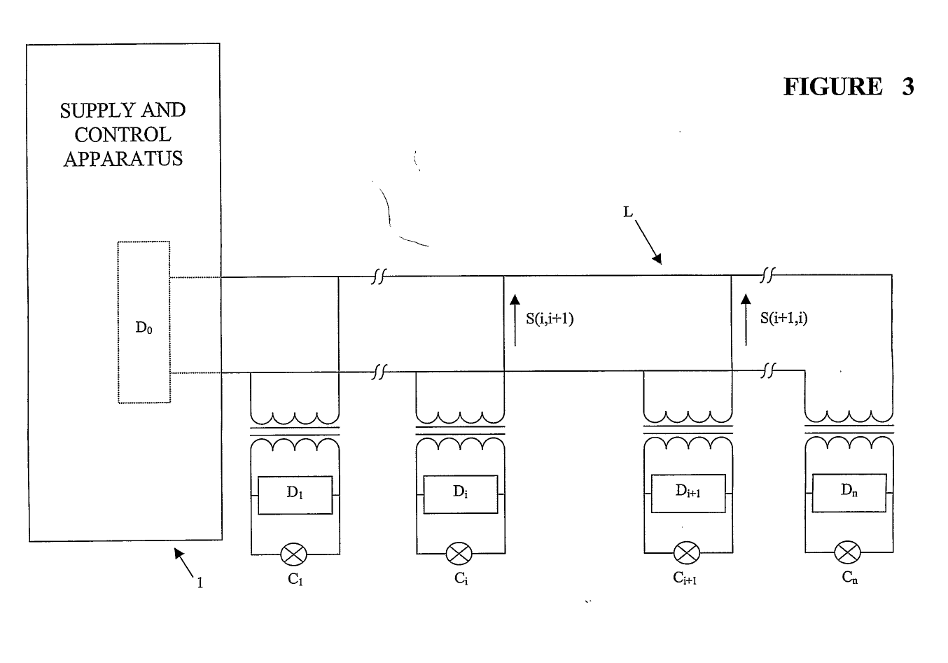

An embodiment variation provides for the connection of said electrical loads C₁, . . . , Cᵢ, Cᵢ₊₁, Cᵢ₊₂, . . . , Cⱼ, Cⱼ₊₁, . . . , Cₙ, branching from the electrical circuit L powered by the power supply and control apparatus 1, as shown in FIG. 3; the control and information signals are managed similarly to the case described above, wherein the electrical loads are connected in cascade with each other. In particular, the first and second control signal S(i,i+1), S(i+1,i), respectively transmitted by the first and second auxiliary device Dᵢ, Dᵢ₊₁, can be sent without distinction on a specific electrical conductor of line L, as shown in FIG. 3, or sent in a sequence on both conductors of line L. The same applies to the information signals, if the transmission means consists of the same electrical line L.

In this case, the power supply and control apparatus 1 comprises a single electrical load, of which only the associated auxiliary device D₀ is indicated, connected branching at the beginning of the electrical line L and belonging to said plurality of electrical loads C₁, . . . , Cᵢ, Cᵢ₊₁, Cᵢ₊₂, . . . , Cⱼ, Cⱼ₊₁, . . . , Cₙ since the control and information signals are managed similarly, as described above.

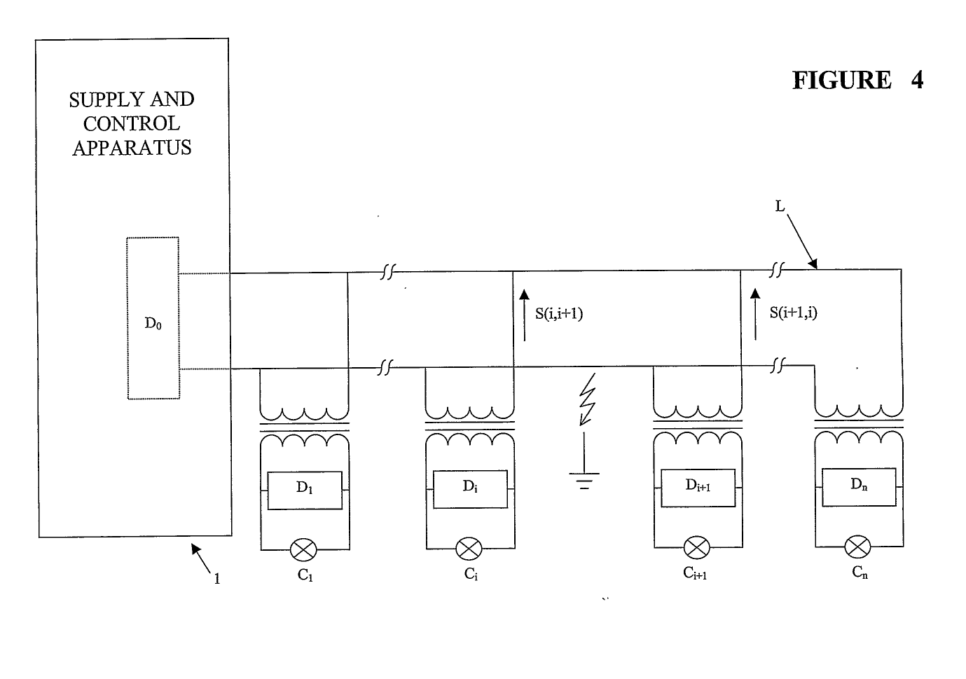

A possible ground failure on the electrical line L is shown in FIG. 4: in that case, as discussed above, the first load Cᵢ and the second load Cᵢ₊₁ receive relevant altered control signals and transmit information signals to the power supply and control apparatus 1, by means of conveyed waves or electromagnetic waves, according to the modes described above and to which reference shall be made.

It should be noted that the reciprocal communication between adjacent auxiliary devices, and between the latter and the power supply and control apparatus 1, can occur for example by periodic cycles; the lower or higher criticality (lighting system of an airport) of a circuit can be managed by adjusting the cycle time within wide time ranges.

A further embodiment variation is described hereinafter, always with reference to a power supply and control apparatus 1 that powers a plurality of electrical loads C₁, . . . , Cᵢ, Cᵢ₊₁, Cᵢ₊₂, . . . , Cⱼ, Cⱼ₊₁, . . . , Cₙ on an electrical line L, arranged in cascade with each other or branching from the same line; in particular, a generic electrical load and the associated auxiliary device are considered, respectively defined as first electrical load Cᵢ and first auxiliary device Dᵢ, for convenience of description. Such variation provides for:
transmitting an identification signal Id(A,i) from the power supply and control apparatus 1 to a first auxiliary device Dᵢ, associated to a corresponding first load Cᵢ belonging to said plurality of electrical loads;
receiving the first identification signal Id(A,i) by the first auxiliary device Dᵢ;
transmitting, on the electrical line L, at least a first response signal Risp(i,A) from the first device Dᵢ to the power supply and control apparatus 1;
receiving the first response signal Risp(i,A) by the power supply and control apparatus 1;
analysing, by the power supply and control apparatus 1, the first response signal Risp(i,A) for detecting any predetermined alteration thereof.

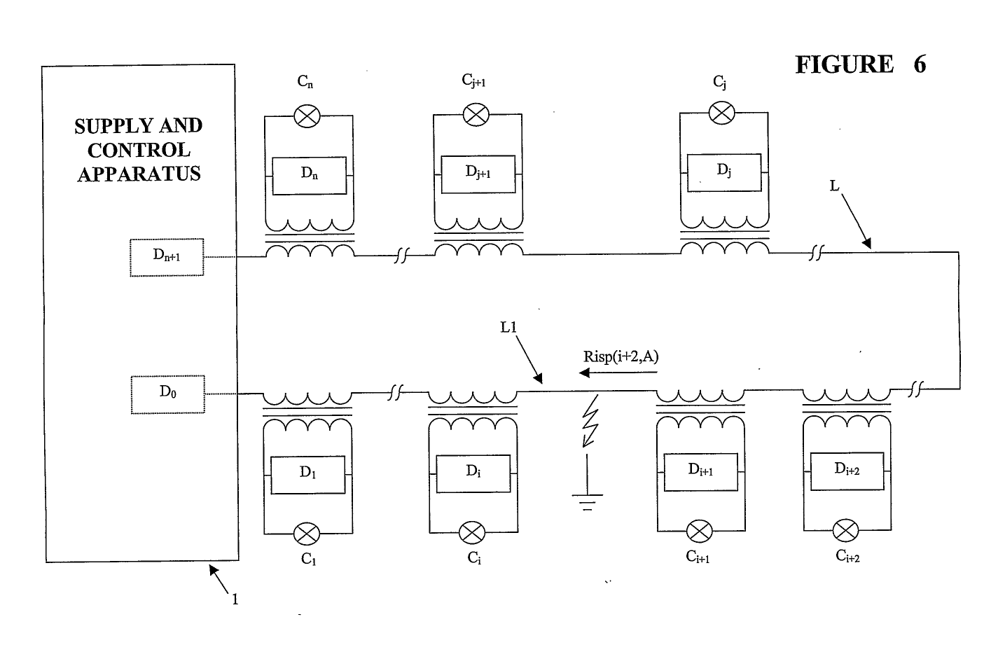

According to what follows from the above remarks, there is a communication, for example of periodic type, between the power supply and control apparatus 1 and any auxiliary device associated to a generic electrical load, belonging to the plurality of electrical loads mentioned above. With reference for example to FIG. 6, according to which the electrical loads are arranged in series on the power supply line L, the response signal Risp(i+2,A), transmitted by the auxiliary device Dᵢ₊₂, undergoes an alteration of the values and patterns during the passage through the portion of faulty circuit L1: as already said, a signal thus altered, transmitted on an electrical line by means of conveyed waves and with frequencies falling within certain ranges, differs from any other anomaly or noise that could occur thereon. Information thus results, relating to the presence of a ground failure in the circuit portion comprised between device Dᵢ₊₂ and the power supply and control apparatus 1.

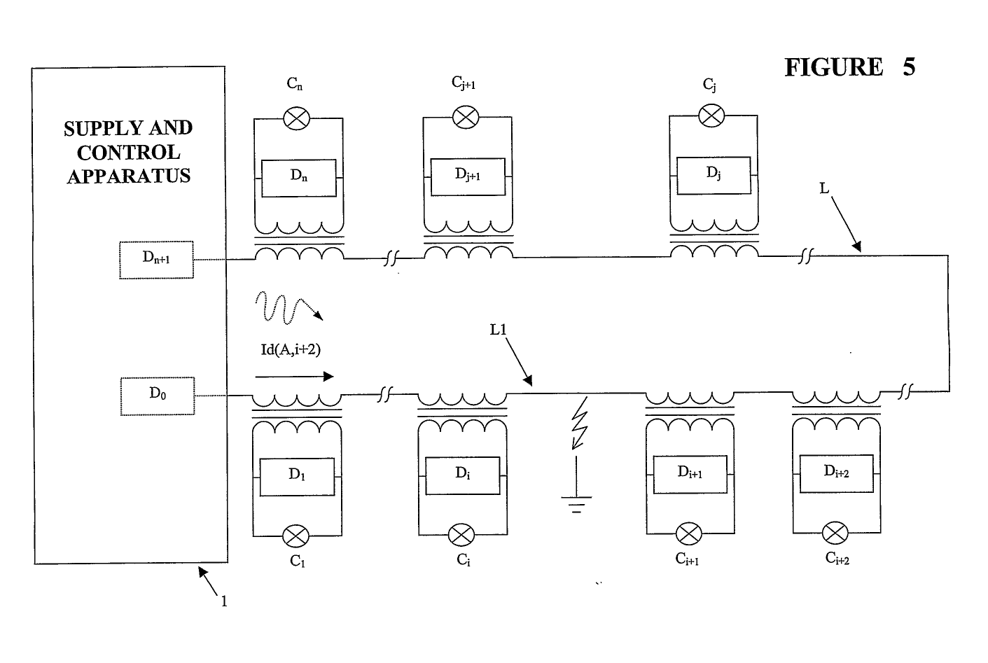

By way of an example, if the power supply and control apparatus 1 communicates respectively with the auxiliary devices of loads C₁, C₂, . . . , Cᵢ, Cᵢ₊₁, Cᵢ₊₂, . . . , Cⱼ, Cⱼ₊₁, . . . , Cₙ, according to the above method, see FIG. 5 or 6, any failure in the portion of circuit L1 is detected as soon as said apparatus analyses the response signal Risp(i+1,A) transmitted by the auxiliary device Dᵢ₊₁.

More in general, the location of the portion concerned with a ground failure is made possible by the analysis, by the power supply and control apparatus 1, of the response signals transmitted by the auxiliary devices arranged upstream and downstream of the same failure point.

It is noted that the identification signals sent by the power supply and control apparatus 1 and intended for the corresponding auxiliary devices, can be transmitted by means of conveyed waves (continuous arrow in FIG. 5) or by means of electromagnetic waves (dotted arrow in FIG. 5); along with the response signals, they contain an identification code that makes them unique, allowing the recognition thereof by the devices that receive them (power supply and control apparatus 1 or auxiliary devices).

The power supply and control apparatus 1 comprises electrical loads, connected to the ends of the electrical line L (of which the relevant auxiliary devices D₀, Dₙ₊₁ are indicated) which add up to said plurality of electrical loads C₁, C₂, . . . , Cᵢ, Cᵢ₊₁, Cᵢ₊₂, . . . , Cⱼ, Cⱼ₊₁, . . . , Cₙ, their operation is similar to what described above.

The subject variation can also be applied if the electrical loads C₁, C₂, . . . , Cᵢ, Cᵢ₊₁, Cᵢ₊₂, . . . , Cⱼ, Cⱼ₊₁, . . . , Cₙ are connected branching from the electrical circuit L: this circuit configuration, in particular, is not reported in the annexed tables since what described with reference to the connection of loads in branching (reference to FIGS. 3, 4) and in series (FIGS. 5, 6) applies. The response signals, generated by the auxiliary devices, can be transmitted without distinction on a specific electrical conductor of line L or be sent in a sequence on both conductors of the same line L; the same applies to the identification signals, if the transmission means consists of the same electrical line L. In the event of a ground failure on the electrical line L, the response signals concerning such faulty portion undergo an alteration, as stated, which is then detected and analysed by the power supply and control apparatus 1, in the reception; in this way it is possible to detect the exact portion concerned by the failure even with the loads arranged branching from the electrical line L. In this case, the power supply and control apparatus 1 comprises a single electrical load, connected branching at the beginning of the electrical line L and belonging to said plurality of electrical loads C₁, C₂, . . . , Cᵢ, Cᵢ₊₁, Cᵢ₊₂, . . . , Cⱼ, Cⱼ₊₁, . . . , Cₙ; its function is the same as that described above, to which reference shall be made.

Finally, always with reference to such variation, both with loads connected in series and branching from said electrical line L, it is possible to provide in each auxiliary device, associated to a corresponding load belonging to said plurality of electrical loads, the possibility of analysing the identification signal it receives, coming from the power supply and control apparatus 1. In the following description, a generic electrical load and the associated auxiliary device are considered, respectively defined as first electrical load Cᵢ and first auxiliary device Dᵢ. Such other variation therefore provides for:
transmitting, on said electrical line L, a first identification signal Id(A,i) from the power supply and control apparatus 1 to a first auxiliary device Dᵢ, associated to a corresponding first load Cᵢ belonging to said plurality of electrical loads;
receiving the first identification signal Id(A,i) by the first auxiliary device Dᵢ;
carrying out a first analysis of said first identification signal Id(A,i), by the auxiliary device Dᵢ, in order to detect any predetermined variation thereof;
transmitting at least a first response signal Risp(i,A) from the first device Dᵢ to the power supply and control apparatus 1;
receiving the first response signal Risp(i,A) by the power supply and control apparatus 1;
carrying out a second analysis, by the power supply and control apparatus 1, the first response signal Risp(i,A).

In this case, the first analysis is carried out for recognising any alterations of the first identification signal Id(A,i) due to the passage of the latter through a portion concerned by a ground failure; as already mentioned several times, a signal thus altered, transmitted on an electrical line by means of conveyed waves and with frequencies falling within certain ranges, differs from any other anomaly or noise that could occur thereon. The first auxiliary device Dᵢ, then, sends the information relating to such first analysis, along with other data for example concerning the operating status of the electrical load associated thereto, to the power supply and control apparatus 1, by means of conveyed waves or by means of electromagnetic waves; the latter, in turn, receives and carries out a second analysis on the first response signal Risp(i,A). In this way, if the first identification signal Id(A,i) has passed on a portion with ground failure and the first response signal Risp(i,A) is sent by means of conveyed waves, for example, said apparatus 1 carries out the second analysis of the last signal in order to check the relevant further alteration besides decoding the associated information contents; this is useful, for example, when a certain time elapses between transmission of the first identification signal Id(A,i) and reception of the response signal Risp(i,A), in order to implement an even more effective control of the electrical line L.

The advantage of the present invention is that it defines a method for detecting and locating a ground failure in an electrical line, which is capable of detecting and locating the failure point in an electrical circuit consisting of loads in cascade with one another, branched from a power supply line or even generally, connected to the line itself; such location, moreover, occurs in very short times, within seconds, considerably shorter than the currently adopted methods.

The detection of the portion concerned with the failure allows the specialised personnel to intervene and remove the portions of cable relating to such circuit portion from the sheath and insert an intact portion of the power supply cable into such sheath.

It is understood that the above is described by way of a non-limiting example and therefore any practical-application variations fall within the scope of protection of the invention, as described above and claimed hereinafter.

1. A method for detecting and locating a ground failure in an electrical line (L) to which there are connected electrical loads powered by a power supply and control apparatus (1), each electrical load consisting of a load element and of an auxiliary device, electrically connected to each other, characterised in that it provides for:
a. transmitting, on said electrical line (L), at least one first control signal (S(i,i+1)) from a first auxiliary device (Dᵢ), associated to a corresponding first load (Cᵢ), to a second auxiliary device (Di+1), associated to an adjacent second load (Ci+1);
b. receiving said first control signal (S(i,i+1)), transmitted by the first auxiliary device (Dᵢ), by the second auxiliary device (Di+1);
c. transmitting a first information signal (Inf(i+1,(i))), to said power supply and control apparatus (1), by said second auxiliary device (Di+1).

2. A method for detecting and locating a ground failure in an electrical line (L) to which there are connected electrical loads powered by a power supply and control apparatus (1), each electrical load consisting of a load element and of an auxiliary device, electrically connected to each other, characterised in that it provides for:
a. transmitting, on said electrical line (L), at least one first control signal (S(i,i+1)) from a first auxiliary device (Dᵢ), associated to a corresponding first load (Cᵢ), to a second auxiliary device (Di+1), associated to an adjacent second load (Ci+1);
b. transmitting, on said electrical line (L), at least a second control signal S(i+1,i) from said second auxiliary device (Di+1), associated to said adjacent second load (Ci+1), to said first auxiliary device (Dᵢ), associated to said corresponding first load (Cᵢ);
c. receiving said first control signal (S(i,i+1)), transmitted by the first auxiliary device (Dᵢ), by said second auxiliary device (Di+1);
d. receiving said second control signal (S(i+1,i)), transmitted by said second auxiliary device (Di+1), by said first auxiliary device (Dᵢ);
e. transmitting a first information signal (Inf(i+1,(i))), to said power supply and control apparatus (1), by said second auxiliary device (Di+1).
f. transmitting a second information signal (Inf(i,(i+1))), to said power supply and control apparatus (1), by said first auxiliary device (Dᵢ).

3. A method according to claim 1, characterised in that the transmission of said first information signal (Inf(i+1,(i))) is subject to the reception, by said second auxiliary device (Di+1), of a predetermined alteration of said first control signal (S(i,i+1)) transmitted by said first auxiliary device Dᵢ.

4. A method according to claim 1, characterised in that said first information signal (Inf(i+1,(i))), transmitted by said second auxiliary device (Di+1), comprises at least a portion of said first control signal (S(i,i+1)) received by the latter.

5. A method according to claim 2, characterised in that the transmission of said first information signal (Inf(i+1,(i))) is subject to the reception, by said second auxiliary device (Di+1), of a predetermined alteration of said first control signal (S(i,i+1)) transmitted by said first auxiliary device (Dᵢ).

6. A method according to claim 2, characterised in that the transmission of said second information signal (Inf(i,(i+1))) is subject to the reception, by said first auxiliary device (Dᵢ), of a predetermined alteration of said second control signal (S(i+1,i)) transmitted by said second auxiliary device (Di+1).

7. A method according to claim 2, characterised in that said first information signal (Inf(i+1,(i))), transmitted by said second auxiliary device (Di+1), comprises at least a portion of said first control signal (S(i,i+1)) received by the latter.

8. A method according to claim 2, characterised in that said second information signal (Inf(i,(i+1))), transmitted by said first auxiliary device (Dᵢ), comprises at least a portion of said second control signal (S(i+1,i)) received by the latter.

9. A method according to claim 1, wherein said plurality of electrical loads is connected in series on said electrical line (L), characterised in that said first control signal (S(i,i+1)) concerns the conductor powering said electrical line (L).

10. A method according to claim 2, characterised in that said electrical loads are connected in series on said electrical line (L) and in that the first control signal (S(i,i+1)) and the second control signal (S(i+1,i)) concern the conductor powering said electrical line (L).

11. A method according to claim 1, characterised in that said electrical loads are unitarily connected branching from said electrical line (L) and in that said first control signal (S(i,i+1)) is sent on at least one of the two conductors powering said electrical line (L).

12. A method according to claim 1, characterised in that said electrical loads are unitarily connected branching from said electrical line (L) and in that said first control signal (S(i,i+1)) is sent in a sequence on the one and on the other of the two conductors powering said electrical line (L).

13. A method according to claim 2, characterised in that said electrical loads are unitarily connected branching from said electrical line (L) and in that the first control signal (S(i,i+1)) and the second control signal (S(i+1,i)) are sent on at least one of the two conductors powering said electrical line (L).

14. A method according to claim 2, characterised in that said electrical loads are unitarily connected branching from said electrical line (L) and in that the first control signal (S(i,i+1)) and the second control signal (S(i+1,i)) are sent in a sequence on the one and on the other of the two conductors powering said electrical line (L).

15. A method according to claim 1, characterised in that said first information signal (Inf(i+1,(i))) is transmitted by means of electromagnetic waves.

16. A method according to claim 2, characterised in that said first information signal (Inf(i+1,(i))) and second information signal Inf(i,(i+1)) are transmitted by means of electromagnetic waves.

17. A method according to claim 1, characterised in that said electrical loads are connected in series on said electrical line (L) and the first information signal (Inf(i+1,(i))) is transmitted along the conductor powering said electrical line (L).

18. A method according to claim 2, characterised in that said electrical loads are connected in series on said electrical line (L) and the first information signal (Inf(i+1,(i))) and the second information signal (Inf(i,(i+1))) concern the conductor powering said electrical line (L).

19. A method according to claim 1, characterised in that said electrical loads are connected branching from said electrical line (L) and said first information signal (Inf(i+1,(i))) is sent on at least one of the two conductors powering said electrical line (L).

20. A method according to claim 1, characterised in that said electrical loads are connected branching from said electrical line (L) and in that said first information signal (Inf(i+1,(i))) is sent in a sequence on the one and on the other of the two conductors powering said electrical line (L).

21. A method according to claim 2, characterised in that said electrical loads are connected branching from said electrical line (L) and said first information signal (Inf(i+1,(i))) and second information signal Inf(i,(i+1)) are sent on at least one of the two conductors powering said electrical line (L).

22. A method according to claim 2, characterised in that said electrical loads are connected branching from said electrical line (L) and said first information signal (Inf(i+1,(i))) and second information signal (Inf(i,(i+1))) are sent in a sequence on the one and on the other of the two conductors powering said electrical line (L).

23. A method according to claim 1, characterised in that the transmission of said first control signal (S(i,i+1)) from said first auxiliary device (Dᵢ), associated to a corresponding first load (Cᵢ), is carried out towards a second auxiliary device (Di+1), associated to a second load (Ci+1) adjacent said first load (Cᵢ).

24. A method according to claim 2, characterised in that the transmission of said first control signal (S(i,i+1)) from said first auxiliary device (Dᵢ), associated to a corresponding first load (Cᵢ), is carried out towards a second auxiliary device (Di+1), associated to a second load (Ci+1) adjacent said first load (Cᵢ).

25. A method for detecting and locating a ground failure in an electrical line (L) to which there are connected electrical loads powered by a power supply and control apparatus (1), each electrical load consisting of a load element and of an auxiliary device, electrically connected to each other, characterised in that it provides for:
transmitting at least a first identification signal (Id(A,i)) from said power supply and control apparatus (1) to a first auxiliary device (Dᵢ), associated to a corresponding first load (Cᵢ);
receiving said first identification signal (Id(A,i)), transmitted by said power supply and control apparatus (1), by said first auxiliary device (Dᵢ);
transmitting, on said electrical line (L), at least a first response signal (Risp(i,A)) from said first auxiliary device (Dᵢ) to said power supply and control apparatus (1);
receiving said first response signal (Risp(i,A)), transmitted by said first auxiliary device (Dᵢ), by said power supply and control apparatus (1);
analysing, by said power supply and control apparatus (1), at least a portion of said first response signal (Risp(i,A)), for detecting any predetermined alteration thereof.

26. A method according to claim 25, characterised in that said first identification signal Id(A,i) is transmitted by means of conveyed waves.

27. A method according to claim 25, characterised in that said first identification signal (Id(A,i)) is transmitted by means of electromagnetic waves.

28. A method according to claim 25, characterised in that said electrical loads are connected in series on said electrical line (L) and the first response signal (Risp(i,A)) is transmitted through the conductor powering said electrical line (L).

29. A method according to claim 25, characterised in that said electrical loads are connected in series on said electrical line (L) and the first identification signal (Id(A,i)) is transmitted through the conductor powering said electrical line (L).

30. A method according to claim 25, characterised in that said electrical loads are connected branching from said electrical line (L) and said first response signal (Risp(i,A)) is sent on at least one of the two conductors powering said electrical line (L).

31. A method according to claim 25, characterised in that said electrical loads are connected branching from said electrical line (L) and in that said first response signal (Risp(i,A)) is sent in a sequence on the one and on the other of the two conductors powering said electrical line (L).

32. A method according to claim 25, characterised in that said electrical loads are connected branching from said electrical line (L) and in that said first identification signal (Id(A,i)) is sent on at least one of the two conductors powering said electrical line (L).

33. A method according to claim 25, characterised in that said electrical loads are connected branching from said electrical line (L) and in that said first response signal (Id(A,i)) is sent in a sequence on the one and on the other of the two conductors powering said electrical line (L).
